(19) United States
(12) Patent Application Publication
(10) Pub. No.: US 2026/0293621 A1
(43) Pub. Date: Sep. 24, 2026

(54) METHOD FOR MANUFACTURING A RESISTIVE LAYER

(71) Applicant: COMMISSARIAT A L'ENERGIE ATOMIQUE ET AUX ENERGIES ALTERNATIVES, Paris (FR)

(72) Inventors: Christine LAURANT, Grenoble Cedex 09 (FR); Emmanuel AUGENDRE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/131,432

(22) PCT Filed: Nov. 20, 2023
(86) PCT No.: PCT/EP2023/082341

§ 371 Date: May 27, 2026

(30) Foreign Application Priority Data
Nov. 23, 2022 (FR) FR2212220

(51) Int. Cl. H10P 90/00; H10W 10/00; H10W 10/10

(52) U.S. Cl. CPC H10P 90/1906; H10W 10/011; H10W 10/181

(57) ABSTRACT

The invention relates to a method for manufacturing a stack comprising the provision of an initial stack comprising a baseplate substrate with the basis of a first material and a first insulating layer comprising an array of walls constituted of a first insulating material separated by trenches, the filling of the trenches by a second insulating material, thus forming a second insulating layer, and the formation of a semiconductive film on the second insulating layer.

### TECHNICAL FIELD OF THE INVENTION

The present invention relates to the manufacturing of resistive layers, and more specifically, the manufacturing of substrates comprising a semiconductive layer surmounting an insulating layer, such as SOI (Silicon On Insulator) substrates. It has, for example, a particularly advantageous application in the field of radiofrequency (RF) components.

### PRIOR ART

To improve the performance of microelectronic components, and more specifically RF components, a focus of major development relates to the improvement of SOI-type substrates. It is, in particular, common, to favour the integrity of the signals, to provide a highly resistive base (or baseplate) and to insert a layer for trapping free carriers between the base and the buried oxide, commonly called BOX. The function of this trapping layer is to form a quasi-insulator. It has, in particular, a very high electric resistivity and does not vary with bias (Fermi level pinning).

In addition, in the field of radiofrequencies, it is desirable to have a substrate making it possible that the integrity of the signals is independent of the operating temperature of the device, for example to produce communicating objects subjected to variable temperature in a wide range. As an example, certain devices can be subjected to temperatures varying from −75° C. to 200° C.

Several types of trapping layers have been explored in the past.

The most widespread trapping layers are made of non-doped polycrystalline silicon (poly Si). Numerous defects present at the grain boundaries of this material ensure the trapping function, which results in a resistivity being able to reach up to 10 kΩ·cm, that is 1000 Ω·m. The performance of these types of trapping layers have, in particular, been studied in the document, “RF Performance of a Commercial SOI Technology Transferred Onto a Passivated HR Silicon Substrate”, Dimitri Lederer and Jean-Pierre Raskin, IEEE Trans. Electr. Dev. Vol. 55, No. 7, July 2008. This solution, however, does not offer a sufficient stability of the electric resistivity faced with temperature variations, which degrades the performance of the device. The electric resistivity of the assembly constituted of the highly resistive silicon base and of the poly Si trapping layer indeed highly varies with temperature.

Other trapping layers are made of porous silicon. Using this insulating material makes it possible to obtain a linearity slightly dependent on the surrounding environment for certain porosification conditions. These conditions have been investigated in the document, “Small- and Large-Signal Performance Up To 175° C. of Low-Cost Porous Silicon Substrate for RF Applications”, M. Rack et al., IEEE Trans. Electr. Dev. 2018. This material, however, has two major disadvantages: a high thermal resistivity limiting the dissipatable power and a low mechanical rigidity complicating its integration in an SOI substrate and its use in a foundry.

A third solution, in particular, has been disclosed in document U.S. Pat. No. 7,067,890 B2. It consists of the formation in a silicon substrate, of an array of walls 2 separated by trenches 3 (FIG. 9A), then the oxidation of these walls 2 until their coalescence (FIG. 9B). The document defines an optimal relationship linking the width Iₜ of the trenches 3 to the width Iₘ of the walls: 0.46*Iₜ=0.53Iₘ. This method makes it possible to obtain a locally very thick oxide (around 10 μm=10⁻⁶ m). The mechanical strength of the assembly thus obtained is better than that of the porous silicon trapping layers. However, the thermal conductivity of the oxide is of the same order (around 1 W/mK) as that of the porous silicon (around 0.5 W/mK), the two latter being low before that of silicon (close to 140 W/mK). The same problem of dissipating the power described for the porous silicon layers therefore also occurs in the scope of this solution. Moreover, the production of thick oxide by the method described in document U.S. Pat. No. 7,067,890 B2 is extremely sensitive to variations of dimensions of the walls 2 and of the trenches 3. If the ratio Iₜ/Iₘ is greater than 0.53/0.46, empty spaces will remain in the trenches 3 after total oxidation of the walls 2, which is unfavourable to the discharge of heat. Conversely, if the ratio Iₜ/Iₘ is less than 0.53/0.46, the trenches 3 will be filled before the total oxidation of the walls, leaving non-oxidised silicon regions in the layer, at the expense of RF performance. Furthermore, this solution does not have a sufficient stability faced with temperature variations.

The present invention therefore aims to propose a simple solution making it possible to limit at least some of the disadvantages of known solutions. For example, the present invention therefore aims to propose a simple solution making it possible to obtain a buried insulating layer having a good mechanical strength, a satisfactory thermal resistivity and a limited thermal dilatation contrast with the substrate.

Other aims, features and advantages of the present invention will appear upon examining the description below and the accompanying drawings. It is understood that other advantages can be incorporated.

### SUMMARY OF THE INVENTION

To achieve the aims mentioned above, a first aspect of the invention relates to a method for manufacturing a stack comprising the following step:
a. Providing at least one initial stack comprising:
   i. a baseplate substrate with the basis of a base material having a thermal dilatation coefficient called base α,
   ii. a first insulating layer surmounting the baseplate substrate, the first insulating layer being with the basis of a first insulating material, the first insulating material having a first thermal conductivity λ₁ and a first thermal dilatation coefficient α₁, the first insulating layer comprising an array of trenches.

The method is characterized in that it also comprises at least the following steps:
b. Filling the trenches by a second insulating material having a second thermal conductivity λ₂ and a second dilatation coefficient α₂, thus forming a second insulating layer, the second thermal conductivity λ₂ being different from the first thermal conductivity λ₁, α₁ and α₂ being greater than 0.3 ppm/K, and
c. Forming a semiconductive film above the second insulating layer.

The buried insulating layer is, in this case, constituted, in particular, by the first insulating layer and the second insulating layer.

Using a second insulating material makes it possible to not be limited to the thermal conductivity and/or electric resistivity and/or thermal dilatation values that the materials can offer, for which it is possible to opt for the baseplate substrate. In particular, using a second insulating material having a thermal conductivity greater than that of the first insulating material makes it possible to optimise the power being able to be dissipated by the buried insulating layer. It is also possible to use materials, the average of which of the thermal dilatation coefficients is close to that of the baseplate material. In this sense, using several materials for producing the buried insulating layer makes it possible to achieve the physical properties that it would be impossible to achieve, by being limited to one single material needing to both ensure the baseplate substrate, electric insulator and thermal conductor role.

The solution which would consist of depositing a thick layer of an insulator having a thermal conductivity greater than that of the baseplate substrate, for example silicon nitride (Si₃N₄), would be limited by the thermal dilatation coefficient (GTE) difference between the silicon baseplate substrate and the nitride layer (and most high thermal conductivity insulators), which would generate unacceptable deformations during thermal treatment steps linked to the manufacturing or to the use of the substrates.

Furthermore, the wall array structure gives the layer a good mechanical strength, and thus makes it possible to minimise the deformation of the layer, with respect to a continuous layer of one single material. This advantage is particularly interesting, when the method is used to form a solid plate insulating layer. This is conveyed, in particular, in this context by an arrow lower than when the buried insulating layer is constituted of a conventional continuous layer.

Another aim of the invention relates to a microelectronic device comprising a stack of layers, said stack comprising, from a lower face of the stack:
a. a baseplate substrate,
b. a buried insulating layer comprising:
   i. a first insulating layer with the basis of a first insulating material and comprising a plurality of walls, the first insulating material having a first thermal conductivity λ1 and a first dilatation coefficient α₁,
   ii. a second insulating layer with the basis of a second insulating material and extending at least into the trenches separating the walls, the second insulating material having a second thermal conductivity λ2 and a second dilatation coefficient α₂, the second thermal conductivity λ₂ being different from the first thermal conductivity λ₁, and preferably with 0.6≤I(α₂+α₁)/2αI≤1.7, α₁ and α₂ being greater than 0.3 ppm/K,
c. a semiconductive film.

By microelectronic device, this means any type of device produced with microelectronic means. These devices include, in particular, in addition to devices with a purely electronic purpose, micromechanical or electromechanical devices (MEMS, NEMS, etc.) as well as optical or optoelectronic devices (MOEMS, etc.).

This can be a device intended to ensure an electronic, optical, mechanical function, etc. This can also be an intermediate product only intended for the production of another microelectronic device. The method and the device according to the present invention are particularly advantageous for forming a device for radiofrequency (RF) applications.

### BRIEF DESCRIPTION OF THE FIGURES

The aims, objectives, as well as the features and advantages of the invention will best emerge from the detailed description of an embodiment of the latter, which is illustrated by the following accompanying drawings, wherein:

FIGS. 1A to 1L illustrate the steps of a first example of a method for forming a stack according to one of the embodiments of the invention. FIGS. 1A to 1E Illustrate, more specifically, the steps of forming an initial stack represented in FIG. 1E, from which other steps are carried out to achieve a stack according to the invention. FIG. 1A illustrates the provision of a substrate.

FIG. 1B illustrates the deposition of a lithographic mask on the substrate.

FIG. 10 represents the formation of trenches in the substrate through the lithographic mask, thus forming an array of walls in the substrate.

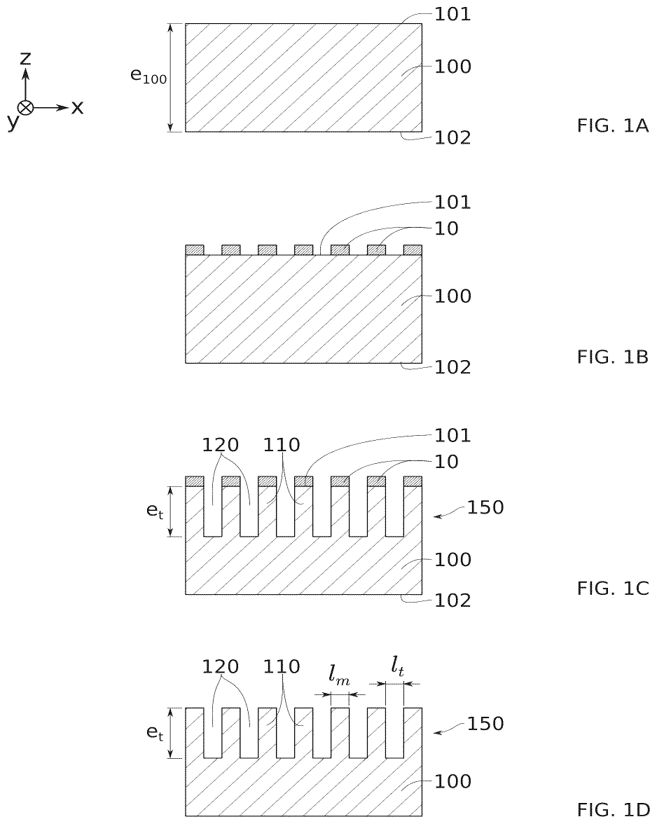

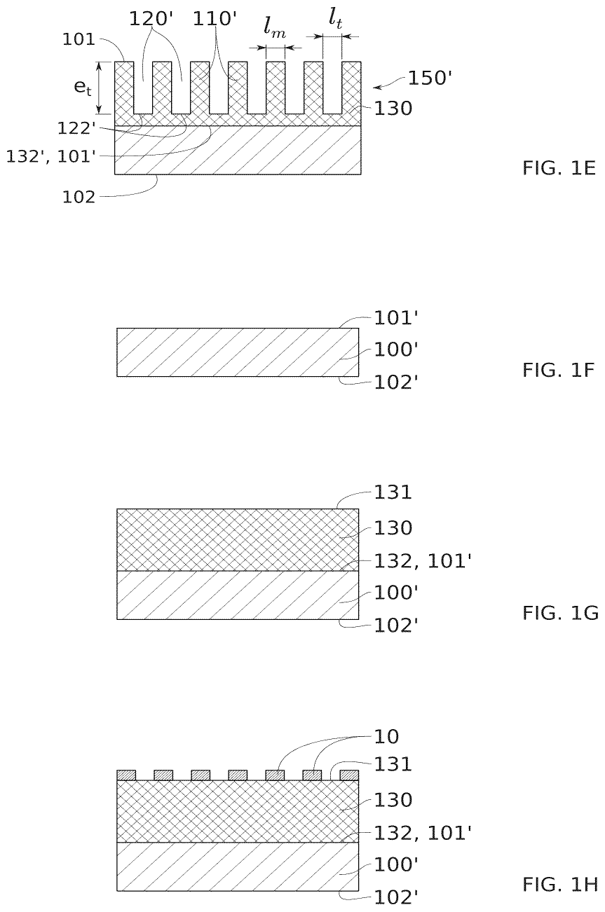

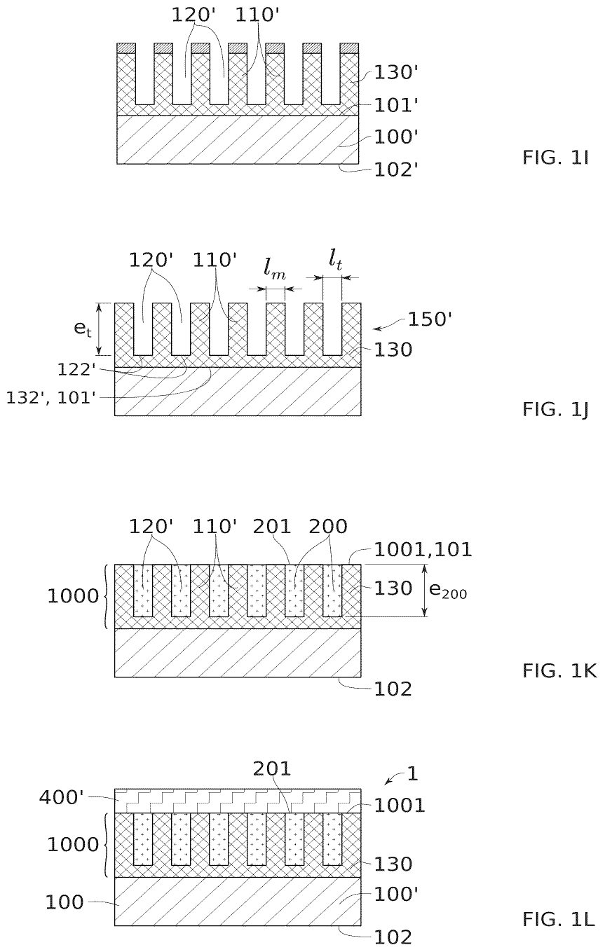

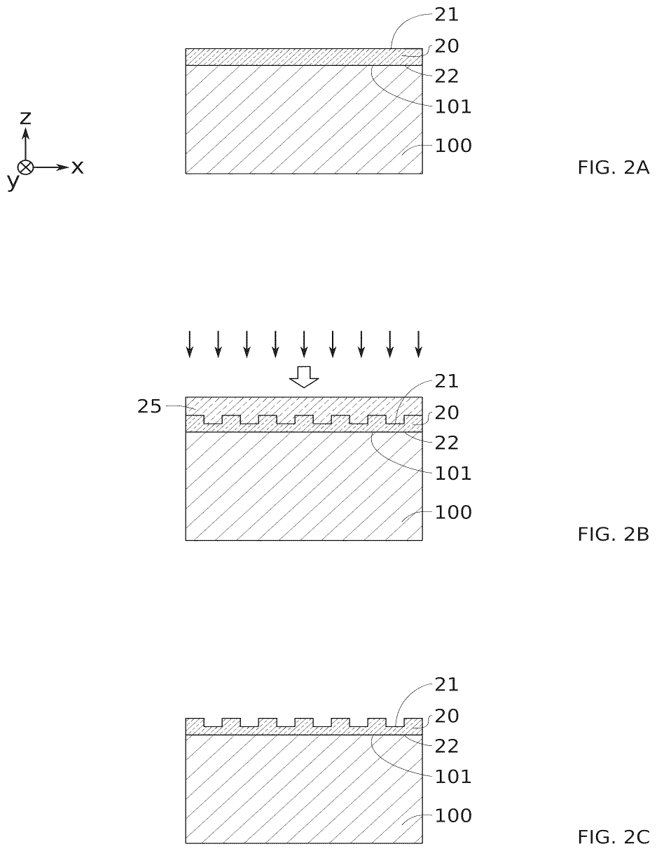

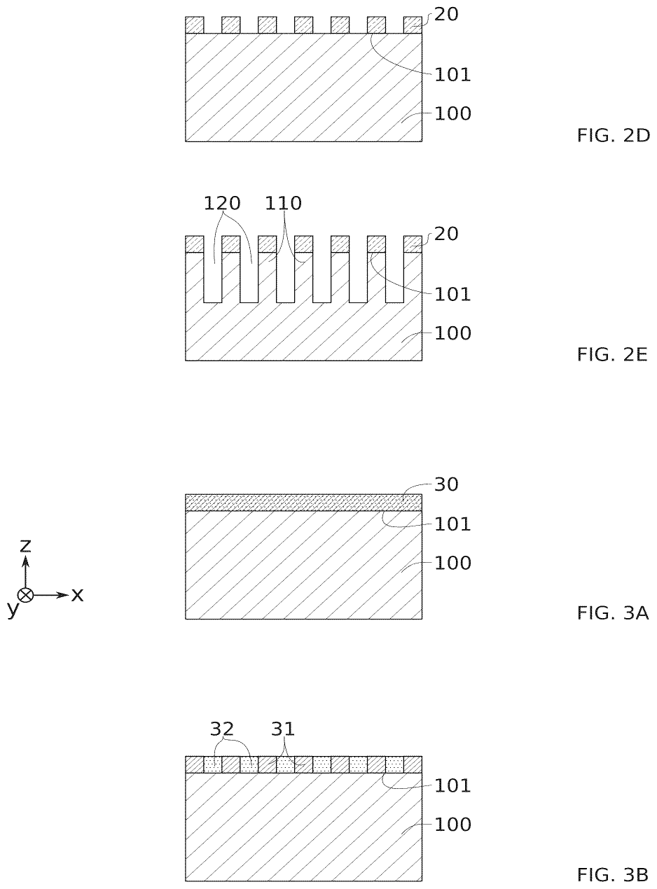

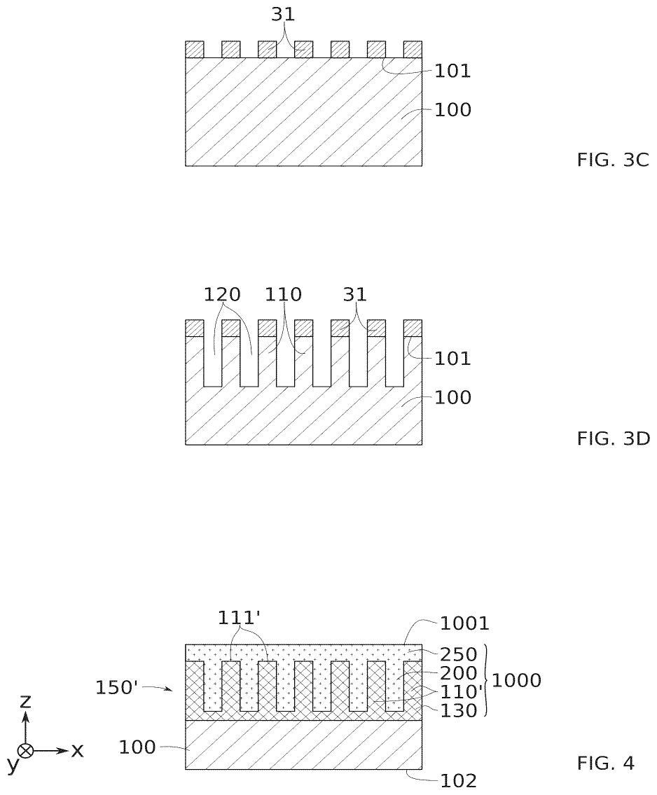

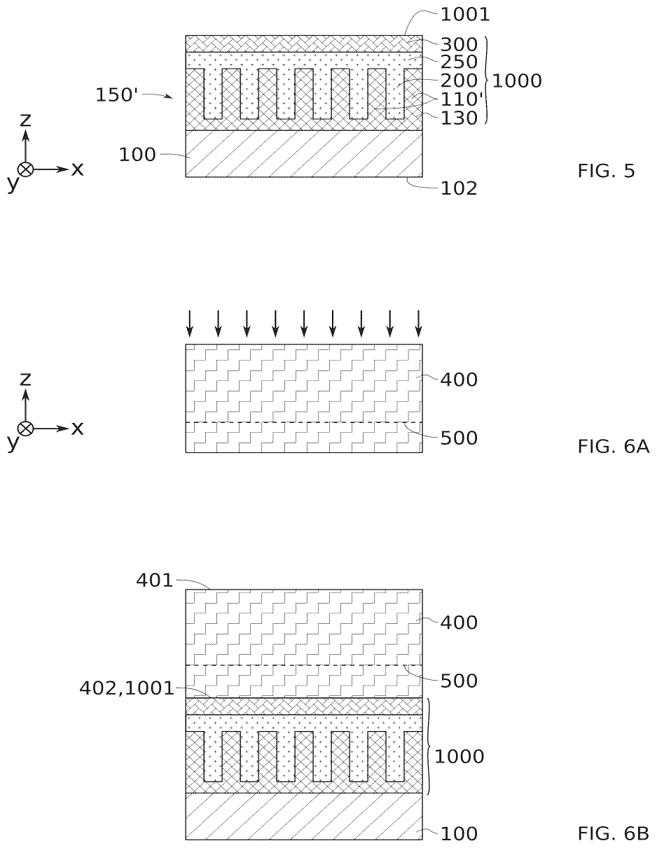

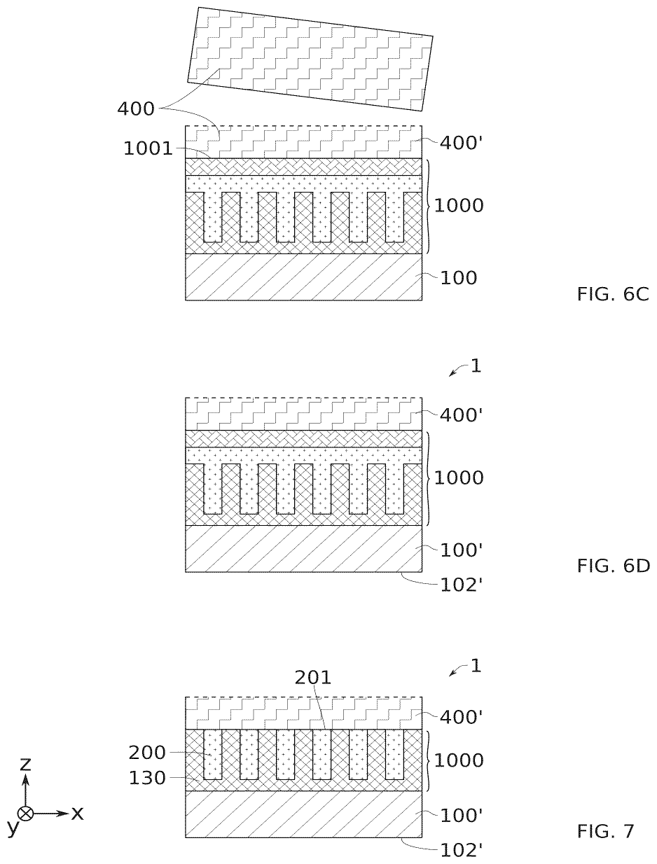

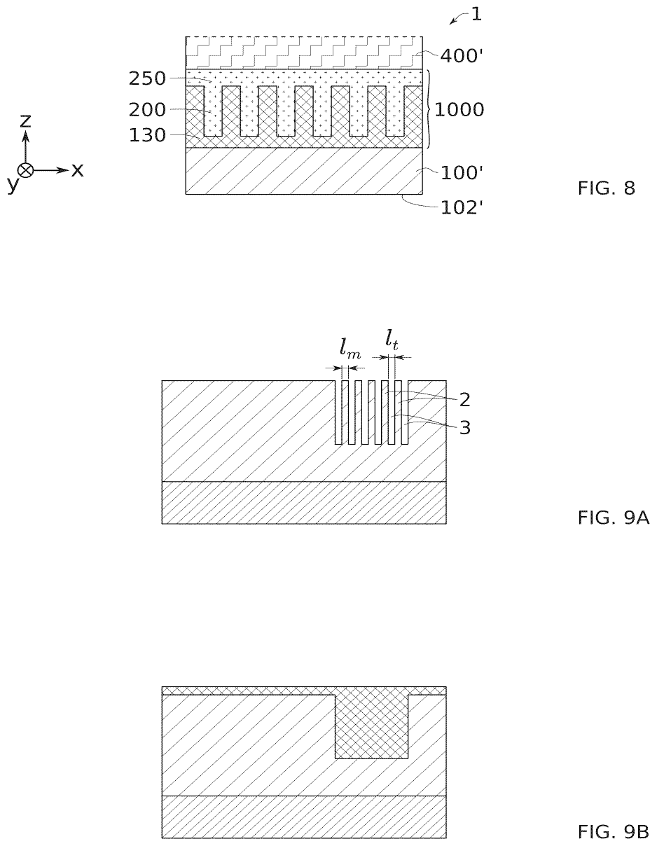

FIG. 1D illustrates the removal of the lithographic mask.

FIG. 1E illustrates a step of transforming the material constituting the walls made of a first insulator, thus forming a first insulating layer.

FIGS. 1F to 1J illustrate the steps of forming the initial stack represented in FIG. 1J, from which other steps are carried out to achieve a stack according to the invention. FIG. 1F illustrates the provision of a baseplate substrate.

FIG. 1F illustrates the formation of a first initial insulating layer on the baseplate substrate.

FIG. 1G Illustrates the deposition of a lithographic mask on the first initial insulating layer.

FIG. 1I represents the formation of trenches in the first initial insulating layer through the lithographic mask, thus forming an array of walls in the first initial insulating layer.

FIG. 1J illustrates the removal of the lithographic mask.

FIG. 1K represents a step of filling the trenches with a second insulating material, thus forming a second insulating layer.

FIG. 1L illustrates a step of forming a semiconductive film on the first insulating layer and the second insulating layer.

FIGS. 2A to 2E illustrate another example of producing trenches in the baseplate substrate implementing a nanoprinting technique. FIG. 2A represents the deposition of a resin layer which is printable on the baseplate substrate.

FIG. 2B Illustrates the printing of a pattern on the printable resin using a mould by pressurising the mould on the printable resin and by UV treatment.

FIG. 2C illustrates the removal of the mould.

FIG. 2D illustrates the etching of certain zones of the printable resin layer, so as to form the desired etching mask.

FIG. 2E represents the formation of trenches in the baseplate substrate through the etching mask.

FIGS. 3A to 3D illustrate another example of an embodiment of trenches in the baseplate substrate implementing a technique for self-assembling block copolymers. FIG. 3A represents the deposition of a copolymer layer on the baseplate substrate. The mixture of scratches and dotted lines illustrates the fact that this layer initially comprises two mixed and unordered copolymers.

FIG. 3B illustrates a treatment step making it possible to order the copolymers by alternance of blocks each comprising only one of the two copolymers.

FIG. 3C illustrates the removal of one of the two copolymers selectively to the other, so as to form an etching mask.

FIG. 3D represents the formation of trenches in the baseplate substrate through the etching mask.

FIG. 4 represents an optional step, according to one of the embodiments of the invention, of depositing a continuous layer with the basis of the second insulating material on the second insulating layer and the first insulating layer.

FIG. 5 represents an optional step, according to one of the embodiments of the invention, of depositing a third insulating layer on the continuous layer with the basis of the second insulating material.

FIGS. 6A to 6D represent another example of an embodiment of the step of forming the semiconductive film. FIG. 6A represents the implantation in a semiconductive layer of a layer which is rich in gaseous elements.

FIG. 6B illustrates the bonding of the semiconductive layer on the stack.

FIG. 6C represents a step of cleaving the semiconductive layer at the layer which is rich in gaseous elements, so as to form a semiconductive film.

FIG. 6D illustrates the stack obtained after the step of cleaving the semiconductive layer.

FIG. 7 illustrates a stack according to one of the embodiments of the invention, wherein the semiconductive film is deposited directly on the second insulating layer.

FIG. 8 illustrates a stack according to one of the embodiments of the invention, wherein the semiconductive film is deposited directly on the continuous layer with the basis of the second insulating material.

FIGS. 9A and 9B illustrate a method for obtaining a thick oxide layer according to the prior art.

The drawings are given as examples, and are not limiting of the invention. They constitute principle schematic representations intended to facilitate the understanding of the invention, and are not necessarily to the scale of practical applications. In particular, the thicknesses of the different layers and films are not representative of reality.

### DETAILED DESCRIPTION OF THE INVENTION

Before starting a detailed review of embodiments of the invention, optional features are stated below, which can optionally be used in association or alternatively:

Preferably, the first insulating layer is fully constituted of the first insulating material.

Advantageously, the first insulating material and the second insulating material are distinct from the base material.

After transformation, the trenches extend into the thickness of the first insulating layer. Preferably, the first insulating layer has a lower face, which is fully located under a bottom of the trenches.

According to an advantageous example, 0≤2*I(α₂−α₁)I/(α₂+α₁)≤1.8 and 0≤I(α−α₁)I/α≤2.1. In this way, the thermal dilatation coefficients of the first insulating layer and of the second insulating layer, on the one hand, and of the first insulating layer and of the baseplate substrate, on the other hand, have values which are quite close to one another. This makes it possible to avoid too large thermal dilatation coefficient differences between materials with the basis of layers in contact. This makes it possible to reduce, even avoid, the mechanical deformations being able to occur during temperature variations. This gives a better robustness and a better structural quality to the stack.

According to an example, 0.6≤I(α₂+α₁)/2αI≤1.7. This, there again, makes it possible to ensure a certain proximity of the thermal dilatation coefficient values of the different materials of the stack. This makes it possible to reduce, even avoid, the mechanical deformations being able to occur during temperature variations. This gives a better robustness and a better structural quality to the stack.

According to an example, k₁≤I(λ₂−λ₁)/λ₁I, with 0.3≤k₁.

According to an embodiment, the second thermal conductivity λ₂ is strictly greater than the first thermal conductivity λ₁ (λ₂>λ₁).

According to an example, one from among the first thermal dilatation coefficient α₁ and the second thermal dilatation coefficient α₂ is greater than α and/or the other from among the first thermal dilatation coefficient α₁ and the second thermal dilatation coefficient α₂ is less than α.

According to an example, the first insulating material has a first Young's modulus E₁ and the second insulating material has a second Young's modulus E₂ with E₁≠E₂ preferably with m₁≤I(E₂−E₁)/E₁I, with 0.03≤m₁, E₁ and E₂ being greater than 50 GPa.

According to an example, the step of providing the initial stack comprises the following steps:
a. Providing at least one initial substrate with the basis, preferably constituted, of the base material and having an upper face,
b. Forming in the initial substrate, and from the upper face, an initial array of trenches, the base material remaining between the trenches forming initial walls,
c. Transforming at least the base material on at least one portion of the initial substrate comprising the initial walls of the initial array made of the first insulating material, thus forming the first insulating layer comprising the array of walls separated by the trenches.

According to an example, transforming at least the base material on at least one portion of the initial substrate comprises an oxidation of the base material separating the trenches from one another.

According to an example, the step of forming the initial array of initial walls comprises the implementation of at least one technique from among lithography, nanoprinting, block copolymer self-assembly and laser treatment.

According to an embodiment, the step of providing the initial stack comprises the following steps:
a. Providing the baseplate substrate,
b. Forming a first initial insulating layer, surmounting the baseplate substrate, the first initial insulating layer being with the basis of the first insulating material,
c. Forming, in the first initial insulating layer, the array of trenches, thus forming the first insulating layer.

According to an example, the step of forming the array of walls comprises the implementation of at least one technique from among lithography, nanoprinting, block copolymer self-assembly and laser treatment.

According to an embodiment, the method further comprises, before the step of forming the semiconductive film, a step of continuously forming a continuous layer with the basis of the second insulating material, and preferably made from the second insulating material, directly covering the second insulating layer. According to an example, the continuous layer is insulating. The continuous layer preferably also covers the walls separating the trenches. The continuous layer can optionally be formed at the same time as the second insulating layer, for example during a deposition, preferably conform, simultaneously occurring on the flanks and the tops of the walls separating the trenches. This optional layer improves the electric resistivity of the stack. It also makes it possible to ensure a good solidarity of the different layers comprised in the buried insulating layer. According to an example, the continuous layer can be qualified as a fourth layer.

According to an embodiment, the method further comprises a step of forming a third Insulating layer under the semiconductive film. The third insulating layer thus preferably covers the walls separating the trenches. This optional layer improves the electric resistivity of the stack. It can also be useful for purposes of planarisation of the buried insulating layer and of quality of the interface with the semiconductive film.

According to an embodiment, the walls separating the trenches have a wall width Iₘ′ and the trenches have a trench width Iₜ′ and wherein the ratio Iₜ′/Iₘ′ is between 0.3 and 3, preferably between 0.5 and 1.5. The widths Iₜ′ and Iₘ′ are preferably chosen, such that 0.7≤I(Iₜ′*α₂+Iₘ′*α₁)/((Iₜ′+Iₘ′)*α)I≤1.3.

According to an example, the trenches have a depth eₜ′, with eₜ′, between 5 μm and 20 μm, preferably between 8 μm and 15 μm.

According to an example, Iₘ′ is between 0.5 μm and 4 μm, preferably between 0.8 μm and 1.5 μm.

According to an example, Iₜ′ is between 0.25 μm and 4 μm, preferably between 0.4 μm and 0.8 μm.

According to an example, the second insulating material is made or is with the basis of one from among Al₂O₃, AlN, SiC, Si₃N₄, BeO, a silicon oxynitride and BN.

According to an example, the semiconductive film is with the basis of one from among Si and its alloys, Ge and its alloys, SiC, InAs, InSb, InGaAs, GaN, AlGaN, InGaN, GaAs and InP.

According to an example, the third insulating layer is with the basis of one from among SiO₂, AlN, HFSiON and Al₂O₃.

According to an embodiment of the device, the buried insulating layer further comprises a continuous layer with the basis of the second insulating material directly covering the second insulating layer.

According to an embodiment, the buried insulating layer further comprises a third insulating layer surmounting the second insulating layer.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers at least partially the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only, or this material M and optionally other materials, for example, alloy elements, impurities or doping elements. Thus, a material with the basis of a III-N material can comprise a III-N material added with dopants. Likewise, a GaN-based layer typically comprises GaN and AlGaN or InGaN alloys.

The term “III-V material” makes reference to a semiconductor composed of one or more elements of column III and of column V of Mendeleev's periodic table. Among the elements of column III, there are boron, gallium, aluminium or also indium. Column V contains, for example, nitrogen, arsenic, antimony and phosphorus.

A material of which the electric resistivity is greater than or equal to 1 kilo (10³) ohms metre (1 k Ωm), preferably greater than or equal to 10 k Ωm is qualified as an insulator.

The abbreviation “ppm” means “parts per million”. This term means the fraction equaling 10⁻⁶, that is one millionth.

By “selective etching vis-à-vis” or “etching having a selectivity vis-à-vis”, this means an etching configured to remove a material A or a layer A vis-à-vis a material B or a layer B, and having an etching speed of the material A greater than the etching speed of the material B. The selectivity is the ratio between the etching speed of the material A over the etching speed of the material B. The selectivity between A and B is referenced SA:B.

The expression, “stability of the electric resistivity in temperature” (or “stability of the applied electric field”) can correspond to a maintaining of the resistivity above a given threshold, for example, 10 kΩ·cm, independently of the temperature (or of the applied electric field).

A preferably orthonormal system, comprising the axes x, y, z is represented in FIG. 1A. This system is applicable by extension to the other figures.

In the present patent application, preferably thickness is referred to for a layer, and height is referred to for a structure or a device. The thickness is taken in a direction normal to the main extension plane of the layer, and the height is taken perpendicularly to the base plane XY. Thus, a layer typically has a thickness along z, when it extends mainly along a plane XY, and a projecting element, for example, an insulation trench, has a height along z. The relative terms “on”, “under”, “underlying” preferably refer to positions taken along the direction z.

In the scope of the present invention, the term “array” covers all the distributions of walls separated by the trenches. The array can have a constant step or not. It can extend over the entire surface of the first insulating layer or over only some of its surface.

The steps of the method such as claimed extend, in the broad sense, and can optionally be carried out in several substeps.

An example of a production method will now be described in reference to FIGS. 1A to 1L. This method makes it possible to obtain the stack 1 illustrated in FIG. 1L, comprising a baseplate substrate 100′, an insulating layer 1000, such as a buried oxide, and a semiconductive film 400′. The insulating layer 1000 comprises, in this embodiment, a first insulating layer 130′, itself comprising a plurality of walls 150′ separated by trenches 120′, and a second insulating layer 20.

This production method first consists of the provision of an initial stack, such as Illustrated in FIGS. 1E and 1J. This stack in particular comprises a baseplate substrate 100′ with the basis of a first material, qualified as a base material, and a first insulating layer 130′ comprising an array 150′ of trenches 120′ separated by walls 110′. Two embodiments for producing this initial stack will now be described.

The first of these two embodiments will first be described in reference to FIGS. 1A to 1E. As illustrated in FIG. 1A, in this embodiment, a first step consists of providing a substrate 100 with the basis of the base material, being able to be transformed into an insulating material called first insulating material. Preferably, the substrate 100 is monocrystalline silicon- or polycrystalline silicon-based. Generally, any semiconductor being able to become insulating by oxidation can be considered. It is also possible to opt for a material being able to be transformed into an insulator by ion bombardment. There are thus many considerable materials, which makes it possible, in particular, to have the option to resort to low-cost materials.

The initial substrate 100 has an upper face 101 and a lower face 102 both extending mainly in planes parallel to the plane XY of the orthogonal system. Along the direction Z, it has a thickness e₁₀₀, For example, e₁₀₀ is between 300 μm and 1000 μm.

A second step of this embodiment consists of forming, in the initial substrate 100, an initial array 150 of initial walls 110 separated by initial trenches 120, as is illustrated in FIG. 1D. The initial walls 110 have a width Iₘ measured in the direction X. The initial trenches 120 have a width Iₜ measured in the direction X and a depth eₜ measured in the direction Z. The initial walls 110 thus extend into the initial substrate 100 from its upper face 101 and up to a depth eₜ measured in the direction Z from the upper face 101.

The initial array 150 of initial walls 110 and initial trenches 120 can be achieved from all of the upper face 101 of the initial substrate 100. It can also be achieved from only some of this upper face 101. In a stack 1 manufactured according to this latter embodiment, the parts of the upper face 101 with no initial trenches 120 can be used to electrically connect the semiconductive film 400′ to the substrate 100.

The initial walls 110 and the initial trenches 120 can be formed in different ways. It is, for example, possible to resort to a lithographic technique, such as photolithography. In this embodiment, a photosensitive resin layer is deposited on the upper face 101 of the initial substrate 100. Openings are thus made in the photosensitive resin by exposure through a photolithographic mask, then development. These openings are underlying the initial trenches 120 that are sought to be formed. On the scale of the stack 1, they typically form parallel lines extending mainly in the direction Y. However, during the integration of the stack 1 in a microelectronic device, these lines advantageously do not have a direction preferable to the scale of the device. In this way, the thermal expansion coefficient of the insulating layer 1000 is substantially that of the baseplate substrate 100′ in all the directions of the plane. The photosensitive resin layer thus etched forms an etching mask 10 such as represented in FIG. 18. The initial trenches 120 are then formed by etching through the etching mask 10. It is, for example, possible, if the baseplate substrate 100 is monocrystalline silicon- or polycrystalline-based, to implement a Bosch method, favourable to producing high form factor structures, such as the walls 110. This method alternates a sulphur hexafluoride (SF₆)-based plasma etching and a fluorocarbon chemistry (C₄F₈, C₂F₆, CF₄ or also CHF₃—Ar)-based passivation.

It is also possible, but not compulsory, to deposit a masking layer between the upper face 101 of the substrate 100 and the photosensitive resin layer. The masking layer is typically silicon dioxide-based. It preferably has a thickness greater than 0.5 μm, preferably greater than 0.8 μm. In this embodiment, an etching is performed after developing the photosensitive resin, in its entire thickness, of the masking layer through the photosensitive resin layer, so as to obtain a hard mask underlying the initial walls 110 that are sought to be formed. The etching of the hard mask and the etching of the initial trenches 120 can be performed successively by different methods or, advantageously, during one same etching method. The Bosch method described above can, in particular, be used for the etching of the silicon dioxide hard mask at the same time as for the etching of the initial trenches 120. In any case, the etching of the trenches can be followed by a step of removing potential etching residues.

It must be noted that the etching mask 10 can also be formed by other lithographic techniques, such as electronic lithography, double exposure lithography, or also extreme ultraviolet lithography.

Furthermore, the initial trenches 120 can be achieved in ways other than by lithography.

For example, the step of forming the initial trenches can comprise a nanoprinting step. This embodiment is illustrated in FIGS. 2A to 2E. FIG. 2A represents the deposition of a printable resin layer 20 on the upper face 101 of the initial substrate 100. This printable resin layer 20 has an upper face 21 and a lower face 22 mainly extending into the plane XY of the orthogonal system, the lower face 22 being in contact with the upper face 101 of the initial substrate 100. FIG. 2B illustrates a step of printing a pattern on the printable resin layer 20 using a mould 25. The mould 25 is flattened and pressed against the upper face 21 of the printable resin layer 20, which also undergoes an ultraviolet (UV) treatment, represented in FIG. 2B by all the parallel arrows pointing towards the upper face 21, so as to set the printable resin according to the desired pattern. The printable resin layer 20 is then etched so as to expose only certain zones of the upper face 101 of the initial substrate 100. Finally, the initial trenches 120 are formed in the baseplate substrate by etching through the remaining regions of the printable resin layer 20.

Another alternative to lithography is illustrated in FIGS. 3A to 3D. A copolymer layer 30 is first deposited on the upper face 101 of the initial substrate 100 (FIG. 3A). This layer 30 comprises a mixture of a first polymer and of a second polymer initially unordered. As illustrated in FIG. 3B, the copolymer layer 30 then undergoes a treatment making it possible to order the first polymer and the second polymer in an alternance between blocks of first polymer 31 and blocks of second polymer 32. One of the two polymers is then removed selectively to the other, as illustrated in FIG. 3C, so as to expose certain zones of the upper face 101 of the initial substrate 100. An etching is then performed through the remaining polymer blocks so as to form the initial trenches 120.

Lithography can also be replaced by the deposition of a layer on the initial substrate 100 followed by a laser treatment of this layer, so as to form an array of ripples then being able to be etched so as to there again form an etching mask.

One of the advantages of the last three embodiments mentioned for the formation of the array 150 of initial walls 110 and initial trenches 120 is that they avoid the use of lithographic equipment. In any case, the etching of the initial trenches 120 can be performed by any one of the etching methods mentioned above.

A third step of this embodiment is represented by the passage from FIG. 1D to FIG. 1E. This is the transformation of the base material constituting the initial walls 110, and optionally some of the initial substrate 110 directly underlying the initial walls 110, into a first insulator. This transformation makes it possible to form a first insulating layer 130′ comprising an array 150′ of walls 110′ and of trenches 120′. Thus, the height of the first insulating layer 130′, measured along the axis Z, is greater than or equal to the depth of the trenches 120′. Thus, after transformation, the trenches 120′ therefore extend into the thickness of the first insulating layer 130′. Preferably, they do not extend into the untransformed part of the initial substrate 100. The height of the first insulating layer 130′ is typically constant. The first insulating layer 130′ thus typically has a lower face 132′ extending mainly into a plane parallel to the plane XY. The lower face 132′ of the first insulating layer 130′ is located, along the axis Z, between the lower face 102 and the upper face 101 of the initial substrate 100.

The lower face 132′ of the first insulating layer 130′ is fully located under the bottom 122′ of the trenches 120′.

The transformation step typically comprises an oxidation step, conventionally a wet oxidation. For example, this step makes it possible to transform the silicon initial walls 110 into silica walls 110′. The transformation step can also comprise an ion bombardment step. This ion bombardment can, for example, be carbon, oxygen and/or nitrogen ion-based, in doses making it possible to reach a few percent of atomic concentration to lead to a material having crystalline grains of a size less than 10 nm after rapid annealing above 1000° C. for less than one second with ramps of at least 50° C./s. This ion bombardment can be preceded by a prior Si+ ion bombardment making it possible to amorphise the walls to facilitate their transformation by the implantation of one of the species mentioned above (carbon, oxygen and/or nitrogen).

The first insulating material has the following parameters: a first thermal conductivity λ₁, a first electric resistivity ρ₁, a first Young's modulus E₁ and a first thermal dilatation coefficient α₁.

The thermal conductivity of a material is expressed in the units of the international system in W·m⁻¹·K⁻¹. It can, for example, be evaluated by the so-called 3-omega method.

The thermal dilatation coefficient of a material is expressed in the units of the international system in K⁻¹. It can, for example, be measured by dilatometry: the length or the thickness of a sample is measured, while the latter is subjected to a known temperature variation.

The value of the dimensions characterizing the geometry of the array is able to be modified during the transformation of the initial walls 110 into walls 110′. Therefore, new dimensions are defined, this time relating to the array 150′. The walls 110′ have a width Iₘ′ measured in the direction X. The trenches 120′ have a width Iₜ′ measured in the direction X and a depth e measured in the direction Z. The walls 110′ thus extend into the substrate 100 from its upper face 101 and up to a depth er measured in the direction Z from the upper face 101.

The width Iₘ′ of the walls 110′, the width Iₜ′ of the trenches 120′ and the depth er of the trenches 120′ are, in particular, sized according to the functional requirements of the systems carried by the stack 1, in particular their operating frequency, the losses being able to be tolerated in these systems or also the diaphony. The depth er of the trenches 120′ is typically between 5 and 20 μm. In addition, it is advantageously at least five times greater, preferably ten times greater, than the width Iₘ′ of the walls 110′. The width Iₘ′ of the walls 110′ is typically between 0.5 and 4 μm, while the width Iₜ′ of the trenches 120′ is typically between 0.25 and 4 μm. The width Iₘ′ of the walls 110′ and the width l′ of the trenches 120 are advantageously substantially equal. They are preferably chosen, such that the average of the thermal expansion coefficients α₁ and α₂ of the first insulator and of the second insulator weighted respectively by Iₘ′ and Iₜ′ is between 0.7*α and 1.3*α, and preferably is substantially equal to the thermal expansion coefficient of base α. For example, it is possible to proceed as follows to size the walls 110′ and trenches 120′:
a. Choosing the first insulating material and the second insulating material which will fill the trenches 120′,
b. Fixing the ratio between the width of the walls 110′ and the width of the trenches 120′ so as to satisfy the relationship mentioned above: 0.7≤I(Iₜ′*α₂+Iₘ′*α₁)/((Iₜ′+Iₘ′)*α)I≤1.3,
c. Choosing the depth eₜ′ of the trenches, such that the ratio between the relative permittivity equivalent to all of the first and second insulating materials and the depth eₜ′ lead to a sufficiently low capacitive coupling between the semiconductive film 400′ and the baseplate substrate 100′. For example, it can be sought to achieve a ratio substantially equal to 7/15 μm⁻¹, The equivalent relative permittivity is the average of the relative permittivities of the first and second insulating materials, weighted by Iₘ′ and Iₜ′,
d. Choosing a trench Iₜ′ width value such that the aspect ratio between Iₜ′ and eₜ′ makes the trenches easily fillable. For example, Iₜ′/eₜ′ of around 1/10. Then Iₘ′ is deduced from this.

After transformation of the initial array 150 into insulating array 150′, the initial stack represented in FIG. 1E is obtained. In particular, the untransformed part of the initial substrate 100 corresponds to the baseplate substrate 100′ comprised in the initial stack represented in FIG. 1E. The lower face 132′ of the first insulating layer 130′ is combined with the upper face 101′ of the baseplate substrate 100′. The first insulating layer 130′ thus extends fully above the upper face 101′ of the baseplate substrate 100′, Like the lower face 132′ of the first insulating layer 130′, the upper face 101′ of the baseplate substrate 100′ extends mainly into a plane parallel to the plane XY.

A second embodiment of the step of providing the initial stack will now be described in reference to FIGS. 1F to 1J.

As illustrated in FIG. 1F, In this embodiment, a first step consists of providing the baseplate substrate 100′. The latter has an upper face 101′ and a lower face 102′ both extending mainly into planes parallel to the plane XY of the orthogonal system.

A first initial insulating layer 130 is then deposited on the upper face 101′ of the baseplate substrate 100′.

A second step of this embodiment consists of forming in the first initial insulating layer 130, the array 150′ of walls 110′ separated by the trenches 120′ as is Illustrated in FIGS. 1H and 1I. The trenches 120′ are formed in the thickness of the first initial insulating layer 130. Preferably, the trenches do not extend into the baseplate substrate 100′. The first initial insulating layer 130, wherein the array 150′ of walls 110′ corresponding to the first insulating layer 130′ described above has been formed.

The formation of the walls 110′ and trenches 120′ can pass through the implementation of any, even several techniques described above for the formation of the initial walls 110 and initial trenches 120: lithography (photolithography, electronic lithography, double exposure lithography, extreme ultraviolet lithography), nanoprinting, selective spreading and removal of block copolymers, or also laser treatment. The final etching of the trenches 120′ common to all these techniques must be adapted to the nature of the first insulating material. Thus, in this embodiment, for example, the following chemistries can be used (between brackets, the materials considered for the first insulating material): BCl₃—Ar (for AlN, BeO), O₂—SF₆ (for SiC), CHF₃ (for SION) and O₂—CF₄ (for BN and Al₂O₃).

In this embodiment, no transformation step is necessary. The dimensions of the array after etching therefore correspond to the dimensions It′, Im′, and′ mentioned above and the sizing features of which have already been described.

After removal of the etching mask having been used during the step of forming the array 150, the initial stack illustrated in FIG. 1J is obtained, similar to that obtained (FIG. 1E) by the implementation of the first embodiment of the provision of this initial stack. The continuation of the steps of the method will now be described in reference to FIGS. 1K, 1L and 4 to 8.

During a fourth step illustrated in FIG. 1K, the trenches 120′ are filled by the second insulating material, thus forming a second insulating layer 200. This second Insulating layer 200 is formed of a plurality of regions, each extending into a trench 120. It has a thickness e₂₀₀ measured along the direction Z. The thickness e₂₀₀ of the second insulating layer 200 is preferably substantially equal to the depth er of the trenches 120′. In the current case of a formation of the second insulating layer 200 by conform deposition, a secondary thickness of second insulating material can be defined, deposited from the flanks of the array of walls 110′. This secondary thickness, measured in the plane XY, is substantially equal to Iₜ′/2, Indeed, in a trench 120′, the growth fronts starting with the flanks of the walls 110′ surrounding the trench 120′ joining one another when the secondary thickness is equal to half the width of the trench 120′. This secondary thickness of the second insulating layer 200 is preferably between 5 and 20 μm.

The fact that the second insulating layer 200 is formed in the trenches 120′ of the first insulating layer 130′ gives a good mechanical strength to the assembly. More specifically, the array structure of the first insulating layer 130′ and the complementary shape of the second insulating layer 200 makes it possible to obtain a better mechanical strength that the simple stack of a flat layer of first insulating material and of a flat layer of second insulating material.

The second insulating material has the following parameters: a second thermal conductivity λ₂, a second electric resistivity ρ₂, a second Young's modulus E₂ and a second thermal dilatation coefficient α₂. The widths of the trenches 120′ and walls 110′, the first thermal dilatation coefficient α₁ and the second thermal dilatation coefficient α₂ are advantageously such that the thermal dilatation coefficient of the assembly constituted of the first insulating layer 130′ and of the second insulating layer 200 in the direction X is substantially close to that of the baseplate substrate 100′.

The second insulating material preferably has a high thermal conductivity λ₂. This can, for example, be Al₂O₃, AlN, SiC, Si₃N₄, BeO or also BN. These insulators have, in particular, a better thermal conductivity that SiO₂ being able to typically be used as a first insulator. Indeed, it is advantageously provided that the thermal conductivity λ₂ of the second insulating material is greater than the thermal conductivity λ₁ of the first insulator.

The deposition of the second insulating material in the transformed trenches 120′ is preferably performed by a method making it possible to reach a high conformality. For example, the deposition of the second insulating material is performed by LPCVD (Low Pressure Chemical Vapour Deposition) or by ALD (Atomic Layer Deposition).

Advantageously, but optionally, the deposition of a continuous layer 250 with the basis of the second insulating material on the second insulating layer 200 is provided, after the step of depositing the second insulating layer 200. The continuous layer 250 with the basis of second insulating material extends, in particular, in vertical alignment with the array 150′, More specifically, it covers the tops 111′ of the transformed walls 110′. It can also extend into the transformed trenches 120′, up to a depth dependent on the thickness e₂₀₀ of the second insulating layer. Advantageously, the second insulating layer 200 fully fills the trenches 120′ and the continuous layer 250 does not extend into the transformed trenches 120′. The continuous layer 250 and the second insulating layer 200 thus form a continuous assembly with the basis of second insulating material. This optional step is illustrated in FIG. 4. In this embodiment, the buried insulating layer 1000 comprises the first insulating layer 130′, the second insulating layer 200 and the continuous layer 250.

Advantageously, but optionally, a step of depositing a third insulating layer 300 of thickness e₃₀₀ measured along the direction Z and having an upper face 301 extending mainly into the plane XY of the orthogonal system is provided, after the step of depositing the second insulating layer 200. This third insulating layer 300 is deposited on the second insulating layer 200 or on the continuous layer 250, if such a layer has been deposited. It is with the basis of a third insulating material, being able to optionally be identical to the first insulator. For example, it can be silica-based. The third insulator has the following parameters: a third thermal conductivity λ₃, a third electric resistivity ρ₃, a third Young's modulus E₃ and a third thermal dilatation coefficient α₃.

In this embodiment, the insulating layer 1000 comprises the first insulating layer 130′, the second insulating layer 200, the third insulating layer 300 and optionally the continuous layer 250, as is represented in FIG. 5.

The method can comprise, after the step of depositing the second insulating layer 200 and optional other insulating layers, an optional step of planarising the buried insulating layer 1000. This can be carried out by means of a chemical-mechanical planarisation (CMP) step from the upper face 1001 of the buried insulating layer 1000. In the possibility where a third insulating layer 300 has been deposited on the second insulating layer 200, it is advantageous, in the scope of the planarisation of the buried insulating layer 1000, that the thickness exo is greater than twice, preferably four times, the maximum roughness of the surface of the layer of underlying second insulating material. This avoids the roughness of this surface being transferred to the upper face 301 of the third insulating layer 300. In any case, the CMP step aims for a removal, greater than twice, preferably substantially equal to three times the maximum roughness of the upper face 1001 of the buried insulating layer 1000.

The planarisation can alternatively be obtained by proceeding with a planarising deposition on the upper face 1001 of the buried insulating layer 1000. For example, this can be a hydrogen silsesquioxane (HSQ) deposition.

This optional step in particular aims to prepare the upper face 1001 of the buried insulating layer 1000 in the step of providing the semiconductive film 400′ which will be described below, in particular, when the semiconductive film 400′ is provided by bonding.

A fifth step is represented in FIG. 1L. It consists of the formation of a semiconductive film 400′ on the buried insulating layer 1000. More specifically, the semiconductive film 400′ can directly cover the second insulating layer 200, the continuous layer with the basis of the second insulating material 250 or also the third insulating layer 300, according to if optional layers have been deposited beforehand on the second insulating layer.

The semiconductive film 400′ can, for example, be Si-based, or on the basis of a III-V material, such as InP, GaAs or also GaN. These materials are commonly used for producing RF devices.

According to an embodiment of the method, the formation of the semiconductive film 400′ includes the implementation of a Smart Cut®-type method. An embodiment of this method is illustrated in FIGS. 6A to 6D.

FIG. 6A illustrates the provision of a semiconductive layer 400 having an upper face 401 and a lower face 402 both extending mainly into the plane XY of the orthogonal system. This same figure illustrates the implantation of light ions in the semiconductive layer 400 from its upper face 401 to form an implanted zone 500. The semiconductive layer 400 thus defines, between its upper face 401 and the implanted zone 500, a semiconductive film 400′. The implanted zone 500 extends advantageously parallel to the upper face 401 and to the lower face 402 of the semiconductive layer 400.

As represented in FIG. 6B, the semiconductive layer 400 is then bonded at its upper face 401 onto the upper face 1001 of the buried insulating layer 1000. The carrying out of the optional step of planarising the buried insulating layer 1000 described above makes it possible to improve the quality of the bonding interface between the semiconductive film 400′ and the upper face 1001 of the buried insulating layer 1000.

After the bonding step, the semiconductive layer 400 is subjected to a treatment enabling its weakening at the implanted zone in gaseous elements. As represented in FIG. 60, the semiconductive layer 400 can thus be cleaved. The semiconductive film 400′ of the same material as the semiconductive layer 400 thus remains on the buried insulating layer, and the thickness e₄₀₀ of which along Z depends on the implantation thickness of the implanted zone 500 in the semiconductive layer 400. Thus, the semiconductive film 400′ is transferred onto the stack 1. The stack 1 thus obtained is represented in FIG. 6D. More specifically, this figure illustrates the stack 1 obtained in the embodiment comprising the optional steps of depositing a continuous layer with the basis of the second insulating material 250 and of depositing a third insulating layer 300.

It can also be considered to perform the bonding of the semiconductive layer 400 onto the upper face 1001 of the buried insulating layer 1000 at its lower face 402. The semiconductive film 400 is thus defined between the implanted zone 500 and the lower face 402. Other embodiments of the Smart Cut® method can be implemented. For example, it is possible to choose a semiconductive material for the material of the baseplate substrate 100′. The implantation of light ions to form the implanted zone can thus be performed in the baseplate substrate 100′, for example through the buried insulating layer 1000. It is then possible to proceed with the bonding of a handle on the buried insulating layer (and therefore either on the second insulating layer 200, or on the continuous layer with the basis of the second insulating material 250, or on the third insulating layer 300). Like the semiconductive layer 400 in the embodiment described above, the baseplate substrate 100′ can then be cleaved at the transferred layer of light ions, so as to obtain a semiconductive film. The handle can subsequently be polished so as to form a substrate for the final structure.

The methods being able to be used to provide the semiconductive film 400′ on the buried insulating layer 1000 are not, however, limited to the Smart Cut® methods which have just been described. Any other thin film transfer technique can be considered.

For example, it is possible to bond the semiconductive layer 400 onto the upper face 1001 of the buried insulating layer 1000, then to proceed with honing steps, optionally completed by a CMP polishing step, and etching from its lower face 402, making it possible to thin this layer until obtaining the semiconductive film 400′.

According to another embodiment, the semiconductive film is formed on a fuse layer, itself deposited on a transparent material. The semiconductive film 400′ is bonded onto the upper face 1001 of the buried insulating layer 1000 by direct bonding at the face facing the fuse layer. The fuse layer is then exposed so as to degrade it and detach it from the semiconductive film 400′.

According to another embodiment, the semiconductive film 400′ is epitaxially grown on a weakened zone, for example, by porosification, on the surface of a semiconductive layer. The semiconductive film 400′ is then bonded, at its face facing the weakened zone, on the upper face 1001 of the buried insulating layer 1000. The transfer is then performed by mechanical separation at the weakened layer, for example, by slide insertion or by waterjet.

FIGS. 7 and 8 represent the devices being able to be obtained by the method according to the invention, in the cases where, respectively, no optional layer has been deposited, and where only one continuous layer with the basis of the second insulating material 250 has been deposited optionally.

The method proposed is particularly advantageous for RF applications. In this case, the semiconductive film 400′ will preferably be InP-, GaAs- or GaN-based.

The invention is not limited to the embodiments described above and extends to all the embodiments covered by its scope.

### NUMERICAL REFERENCES

1. stack
10, etching mask
20. printable resin layer
21. upper face of the printable resin layer
22. lower face of the printable resin layer
25. nanoprinting mould
30. polymer layer
31. first polymer block
32. second polymer block
100. initial substrate
101. upper face of the initial substrate
102. lower face of the initial substrate
100′, baseplate substrate
101′. upper face of the baseplate substrate
102′. lower face of the baseplate substrate
110. walls
110′. transformed walls
111′. tops of oxidised walls
120. trenches
120′, transformed trenches
122′, bottom of the trenches
130. first initial insulating layer
131. upper face of the first initial insulating layer
132. lower face of the first initial insulating layer
130′. first insulating layer
132′. lower face of the first insulating layer
150. array of walls
150′, array of oxidised walls
200. second insulating layer
201. upper face of the second insulating layer
250. continuous layer with the basis of second insulating material
300. third insulating layer
301. upper face of the third insulating layer
400. semiconductive layer
401. upper face of the semiconductive layer
402. lower face of the semiconductive layer
400′, semiconductive film
500. implanted zone
1000. buried insulating layer
1001. upper face of the buried insulating layer

1. A method for manufacturing a stack comprising:
providing at least an initial stack comprising:
a baseplate substrate based upon a base material having a thermal dilatation coefficient α, the baseplate substrate having an upper face and a lower face both extending mainly in a plane, and
a first insulating layer surmounting the upper face of the baseplate substrate, the first insulating layer being based upon a first insulating material, the first insulating material having a first thermal conductivity λ₁ and a first thermal dilatation coefficient α₁, the first insulating layer comprising an array of trenches,
filling the trenches with a second insulating material having a second thermal conductivity λ₂ and a second thermal dilatation coefficient α₂, thus forming a second insulating layer, the second thermal conductivity λ₂ being different from the first thermal conductivity λ₁, and α₁ and α₂ being greater than 0.3 ppm/K, and
forming a semiconductive film above the second insulating layer.

2. The method for manufacturing a stack according to claim 1, wherein 0≤2*I(α₂−α₁)I/(α₂+α₁)≤1.8 and 0≤I(α−α₁)I/α≤2.1.

3. The method for manufacturing a stack according to claim 1, wherein k₁≤I(λ₂−λ₁)/λ₁I, with 0.3≤k₁.

4. The method for manufacturing a stack according to claim 1, wherein the second thermal conductivity λ₂ is strictly greater than the first thermal conductivity λ₁.

5. The method for manufacturing a stack according to claim 1, wherein one from among the first thermal dilatation coefficient α₁ and the second thermal dilatation coefficient α₂ is greater than α and the other from among the first thermal dilatation coefficient α₁ and the second thermal dilatation coefficient α₂ is less than α.

6. The method for manufacturing a stack according to claim 1, wherein the first insulating material has a first Young's modulus E₁ and the second insulating material has a second Young's modulus E₂, with E₁≠E₂.

7. The method for manufacturing a stack according to claim 1, wherein providing the initial stack comprises:
providing at least one initial substrate with based upon the base material and having an upper face,
forming in the initial substrate and from the upper face of the initial substrate, an initial array of initial trenches, and
transforming at least the base material on at least one portion of the initial substrate into the first insulating material, thus forming the first insulating layer.

8. The method for manufacturing a stack according to claim 7, wherein transforming at least the base material on at least one portion of the initial substrate comprises oxidizing the base material separating the initial trenches from one another.

9. The method for manufacturing a stack according to claim 1, wherein providing the initial stack comprises:
providing the baseplate substrate,
forming a first initial insulating layer surmounting the baseplate substrate, the first initial insulating layer being based upon the first insulating material, and
after forming the first initial insulating layer, forming in the first initial insulating layer, the array of trenches, thus forming the first insulating layer.

10. The method for manufacturing a stack according to claim 1, further comprising, before forming the semiconductive film, forming a continuous layer based upon the second insulating material directly covering the second insulating layer.

11. The method for manufacturing a stack according to claim 1, further comprising forming a third insulating layer based upon a third insulating material distinct from the second insulating material, under the semiconductive film.

12. The method for manufacturing a stack according to claim 1, wherein the first insulating material remaining between consecutive trenches forms a wall, each wall has a wall width Iₘ′ and the trenches have a trench width Iₜ′, wherein a ratio Iₜ′/Iₘ′ is between 0.3 and 3.

13. The method for manufacturing a stack according to claim 1, wherein the trenches have a depth eₜ′, with eₜ′ being between 5 μm and 20 μm.

14. The method for manufacturing a stack according to claim 1, wherein the second insulating material is made of or is based upon one from among Al₂O₃, AlN, SiC, Si₃N₄, BeO, a silicon oxynitride and BN.

15. The method for manufacturing a stack according to claim 1, wherein the first insulating layer is fully constituted of the first insulating material.

16. The method for manufacturing a stack according to claim 1, wherein the first insulating material and the second insulating material are each distinct from the base material.

17. A microelectronic device comprising a stack of layers comprising:
a baseplate substrate having an upper face and a lower face both extending mainly in a plane,
a buried insulating layer comprising:
a first insulating layer based upon a first insulating material and comprising a plurality of walls, the first insulating material having a first thermal conductivity λ₁ and a first thermal dilatation coefficient α1, the first insulating layer surmounting the upper face of the baseplate substrate,
a second insulating layer based upon a second insulating material and extending at least into trenches separating the walls, the second insulating material having a second thermal conductivity λ2 and a second thermal dilatation coefficient α2, the second thermal conductivity λ2 being different from the first thermal conductivity λ1, α1 and α2 being greater than 0.3 ppm/K, and
a third insulating layer surmounting the second insulating layer, and
a semiconductive film.

18. The method for manufacturing a stack according to claim 6, wherein m₁≤I(E₂−E₁)/E₁I, with 0.03≤m₁ and E₁ and E₂ are greater than 50 GPa.

19. The method for manufacturing a stack according to claim 12, wherein 0.7≤I(1ₜ+′*α₂+1ₘ′*α₁)/((1ₜ+′+1ₘ′)*α)I≤1.3.
